(19) United States
(12) Patent Application Publication
(10) Pub. No.: US 2003/0027420 A1
(43) Pub. Date: Feb. 6, 2003

(54) Method for forming the partial salicide

(75) Inventors: Erh-Kun Lai, Taichung (TW); Shou-Wei Hwang, Chilung (TW); Tung-Cheng Kuo, I-Lan (TW); Yu-Ping Huang, Taichung (TW)

Correspondence Address: LOWE HAUPTMAN GILMAN & BERNER, LLP, 1700 Diagonal Road, Suite 310, Alexandria, VA, 22314, US

(73) Assignee: MACRONIX INTERNATIONAL CO., LTD.

(21) Appl. No.: 09/917,644

(22) Filed: Jul. 31, 2001

(51) Int. Cl. H01L 21/336; H01L 21/44

(52) U.S. Cl. 438/655; 438/299; 438/301; 438/303; 438/656

(57) ABSTRACT

This invention relates to a method for forming the salicide, more particularly, to the method for forming the salicide in the partial region. The present invention uses a silicon layer to be the mask layer to form the salicide in the partial region of the logic circuit. The silicide is formed on the gate and is not formed in the diffusion region, which are in the cell array region. The silicide is formed on the gate and in the diffusion region, which are in the periphery region. The present invention method can make the semiconductor device obtain lower resistance and decrease the leakage defects.

### BACKGROUND OF THE INVENTION

1. Field of the Invention

This invention relates to a method for forming the salicide, more particularly, to the method for forming the salicide in the partial region to form the silicide on the gates which are in the periphery region and cell array region, and in the diffusion region which is in the periphery region. The present invention method can make the semiconductor device obtain lower resistance and decrease the leakage defects.

2. Description of the Prior Art

An increment in device integrity makes the resistance of metal oxide semiconductor (MOS) device source/drain regions gradually climb up and almost equal to the resistance of MOS device channel. In order to reduce the sheet resistance of source/drain regions and to guarantee a complete shallow junction between metal and MOS device, the application of a “Self aligned Silicide” process is gradually steeping into the very large scale integration (VLSI) fabrication of 0.5 micron (μm) and below. This particular process is called “Salicide” for short.

In general, the titanium silicon is usually used in silicide. The titanium silicide is formed to use two sequence steps rapid thermal process. At first, referring to FIG. 1, a silicon substrate 10 is provided and a MOS device and a shallow trench isolation are formed thereon. The MOS device comprises a source/drain region 12 a gate region, and as well as a spacer 18 formed on the sidewalls of the gate region. This gate region comprises a gate oxide layer 14 and a polysilicon layer 16, then using the chemical vapor deposition technique or the magnetron direct current sputtering technique to deposit a titanium metal layer 20 over the MOS and the shallow trench isolation. The thickness of the titanium metal layer 20 is about more than 300 angstroms. Next, a rapid thermal process is performed, wherein part of the titanium metal layer will react with the silicon on the source/drain region and with the polysilicon of the gate region to form a titanium silicide layer. The thickness of this titanium silicide layer is about 600 to 700 angstroms. The structure of this titanium silicide layer is a metastable C-49 phase structure with higher resistivity. Referring to FIG. 2, the unreacted titanium metal and the remained titanium metal are removed by applying the RCA cleaning method. Therefore, the titanium silicide layer 22 is existed on top of the gate region and the source/drain region. Finally, a rapid thermal process is performed again to transform higher resistivity of the C-49 phase titanium silicide structure into lower resistivity of the C-54 phase titanium silicide structure.

In the deep sub-micron device fabrication, the decline of the device driving current that cause by parasitic seties resistance of source/drain can be avoided by siliciding the source/drain. The above can be accomplished by either using simple silicidation of source/drain or self-aligned silicidation, where self-aligned silicidation can accomplish the silicidations of source/drain and gate region at the same time.

In the present logic circuit, the silicide is also needed to be used to decrease the resistance of the conductive layer and to increase the qualities of the semiconductor device. In order to cooperate the operation of the logic circuit, the partial region of the logic circuit will not be formed with the silicide to prevent the leakage defects producing on the semiconductor device. In the traditional salicide process, the silicide is formed on the partial material, which need to form silicide, by using complex steps. In the present semiconductor process, the process efficiency is important. The traditional complex steps, which need more time, are not suitable for the present semiconductor process. The present invention method must be used to increase the efficiency of the process.

### SUMMARY OF THE INVENTION

In accordance with the above-mentioned invention backgrounds, the traditional method can not form the silicide in the partial region of the logic circuit quickly. The main object of the present invention is to decrease the resistance of the word line, which is in the cell array region and periphery region, by using a silicon layer to be the mask layer to form the silicide on the gates, which are in the cell array region and the periphery region, and in the diffusion region, which is in the periphery region successfully.

The second objective of this invention is to avoid the leakage defects occurring in the diffusion region, which is in the cell array region, by using a silicon layer to be the mask layer to form the silicide on the gates, which are in the cell array region and the periphery region, and in the diffusion region, which is in the periphery region successfully.

The third objective of this invention is to decrease the resistance of the periphery region by using a silicon layer to be the mask layer to form the silicide on the gates, which are in the cell array region and the periphery region, and in the diffusion region, which is in the periphery region successfully.

The fourth objective of this invention is to increase the quality of the semiconductor device by using a silicon layer to be the mask layer to form the silicide on the gates, which are in the cell array region and the periphery region, and in the diffusion region, which is in the periphery region successfully.

It is a further objective of this invention to increase the proceeding efficiency of the semiconductor device process by using a silicon layer to be the mask layer to form the silicide on the gates, which are in the cell array region and the periphery region, and in the diffusion region, which is in the periphery region successfully.

In according to the foregoing objectives, the present invention provides a method to decrease the resistance of the word line, which is in the cell array region and periphery region and to avoid the leakage defects occurring in the diffusion region, which is in the cell array region, by using a silicon layer to be the mask layer to form the silicide on the gates, which are in the cell array region and the periphery region, and in the diffusion region, which is in the periphery region successfully. The present invention method can also decrease the resistance of the periphery region. The present invention method can further increase the quality of the semiconductor device and increase the proceeding efficiency of the semiconductor device process.

### BRIEF DESCRIPTION OF THE DRAWINGS

In the accompanying drawing forming a material part of this description, there is shown:

FIG. 1 shows a diagram in forming a titanium layer over the MOS by using the traditional technology;

FIG. 2 shows a diagram in forming a titanium silicide layers on the gate region and source/drain region by using the traditional technology;

FIG. 3 shows a diagram in forming the first oxide layer, nitride layer, and the second oxide layer on the substrate;

FIG. 4 shows a diagram in removing the first oxide layer, nitride layer, and the second oxide layer which are in the periphery region;

FIG. 5 shows a diagram in forming the third oxide layer on the substrate which is in the periphery region;

FIG. 6 shows a diagram in forming a silicon layer on the second oxide layer and the third oxide layer;

FIG. 7 shows a diagram in forming the plural first gates and the plural first diffusion regions in the periphery region and forming the lightly doped drain (LDD) in the plural first diffusion regions;

FIG. 8 shows a diagram in forming the spacer on the sidewalls of the silicon layer which is in the cell array region and the plural first gates; removing the first poly layer which is at the inactive region;

FIG. 9 shows a diagram in forming the source/drain region in the plural first diffusion region;

FIG. 10 shows a diagram in forming a metal layer on the silicon layer which is in the cell array region, the plural first gates, and the plural first diffusion regions;

FIG. 11 shows a diagram in forming the silicide on the silicon layer which is in the cell array region, the plural first gates, and the plural first diffusion regions; and

FIG. 12 shows a diagram in forming the plural second gates and the plural second diffusion region on the second oxide layer.

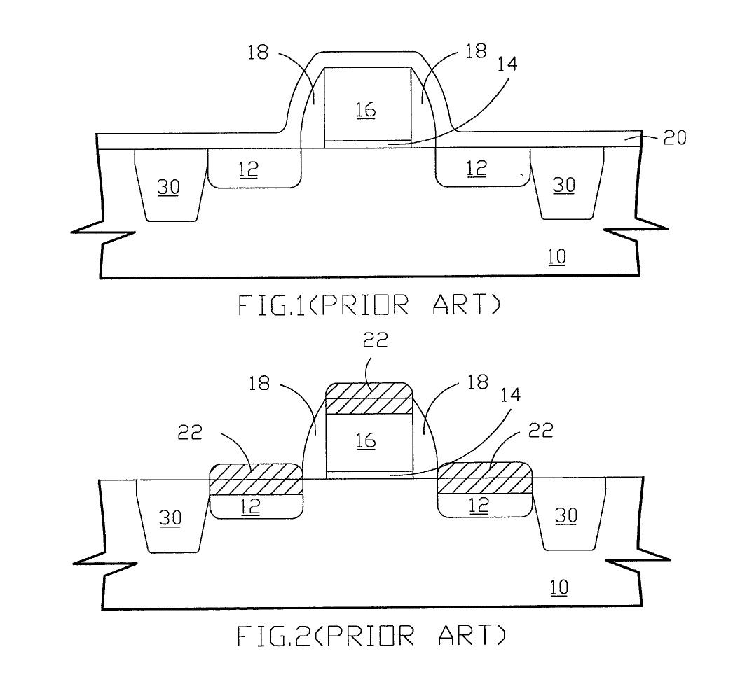

### DESCRIPTION OF THE PREFERRED EMBODIMENT

The foregoing aspects and many of the attendant advantages of this invention will become more readily appreciated as the same becomes better understood by reference to the following detailed description, when taken in conjunction with the accompanying drawings, wherein:

The semiconductor devices, which are in the logic circuit, are interconnected by using the word line and the bit line. The objective of the word line is to define the location of the signals and the objective of the bit line is to judge the types of the signal. Therefore, the word line connects with the gate of the semiconductor device and the bit line connects with the source/drain region of the semiconductor device. Regarding to the word line, it needs higher transmission rate to transmit the data. Therefore, a silicide is formed on the word line and on the gates of the semiconductor device to decrease the resistance of the word line and to increase the transmission rate of the word line by using the present invention method.

The logic circuit is divided into two major region, one is cell array region, the other is periphery region. The function of the cell array region is to save the data in an electric charge mode to the memory device which is in the cell array region. The function of the periphery region is to transmit and to compute the data by using the devices, which are in the periphery region, such as the adder, to treat the data. The data will be transmitted to other regions by using the periphery region after the data is treated. Therefore, the devices which are in the cell array region must be independent with each other to prevent the short circuit defects, which will lost the data. The devices which are in the periphery region must be interconnected with each other to increase the treating rate of the data. This shows that the present invention method must be used to form the silicide on the gate and the diffusion region of the periphery region, to form the silicide on the gate of the cell array region, and to avoid forming the silicide on the diffusion region of the cell array region. This condition will increase the data transmitting ability of the periphery region and prevent the short circuit defects, which will lost the data, occurring in the cell array region.

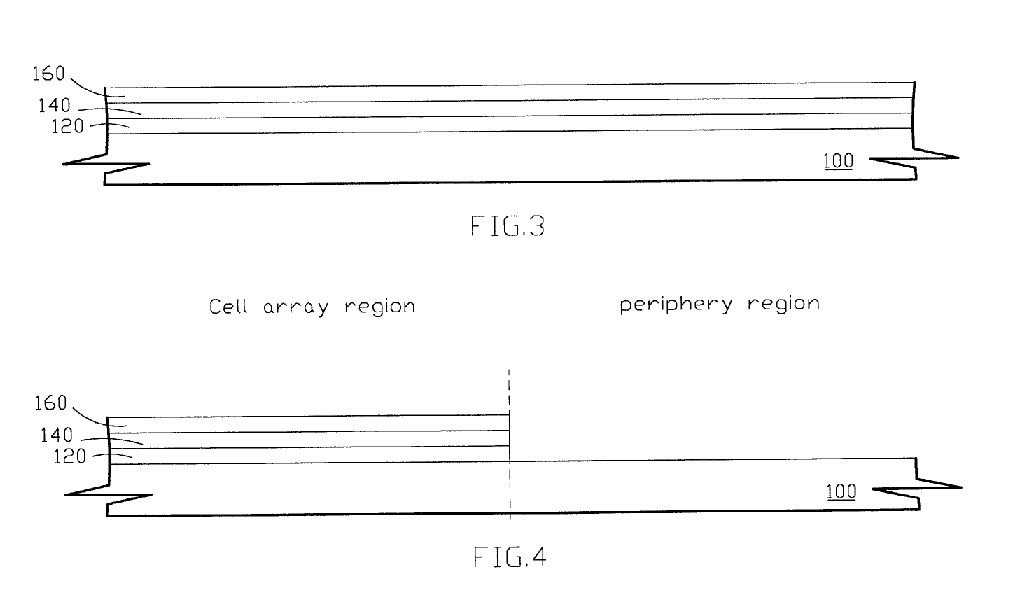

Referring to FIG. 3, a wafer, which comprises a substrate 100, is provided at first and the first oxide layer 120 is formed on the substrate 100. Then a nitride layer 140 is formed on the first oxide layer 120 and the second oxide layer 160 is formed on the nitride layer 140 at last. The thickness of the first oxide layer 120 is usually about 70 to 90 angstroms, the thickness of the nitride layer 140 is usually about 60 to 80 angstroms, and the thickness of the second oxide layer 160 is usually about 60 to 80 angstroms. In the present process, the thickness of the of the first oxide layer 120 is 80 angstroms, the thickness of the nitride layer 140 is 70 angstroms, and the thickness of the second oxide layer 160 is 70 angstroms. Following the width of the process is shorter and shorter, the thickness of the first oxide layer 120, the nitride layer 140, and the second oxide layer 160 will be decreased to conform to the needs of the process.

Referring to FIG. 4, after deciding the cell array region and the periphery region on the wafer, the first oxide layer 120, the nitride layer 140, and the second oxide layer 160 which are in the periphery region are removed by a photolithography and a etching process to show the substrate in the periphery region. Referring to FIG. 5, the third oxide layer 200 is formed on the substrate 100 which is in the periphery region. The thickness of the third oxide layer 200 is usually about 40 to 60 angstroms. In the present process, the thickness of the third oxide layer 200 is 50 angstroms. But following the width of the process is shorter and shorter, the thickness of the third oxide layer 200 will be decreased to conform to the needs of the process. The silicon dioxide (SiO₂) is usually used to be the material of the first oxide layer 120, the second oxide layer 160, and the third oxide layer 200. The silicon nitride is usually used to be the material of the nitride layer 140.

In the embodiment, the different forms dielectric layers are formed on the substrate, which is in the cell array region and the periphery region. The oxide/nitride/oxide sandwich form dielectric layer is formed on the substrate in the cell array region. The oxide layer is formed on the substrate in the periphery region to be the dielectric layer. Following the different needs of the process, the cell array region and the periphery region can use the same form dielectric layer which is formed on the substrate to keep the efficiency of the semiconductor devices. The same form dielectric layer can be the oxide layer.

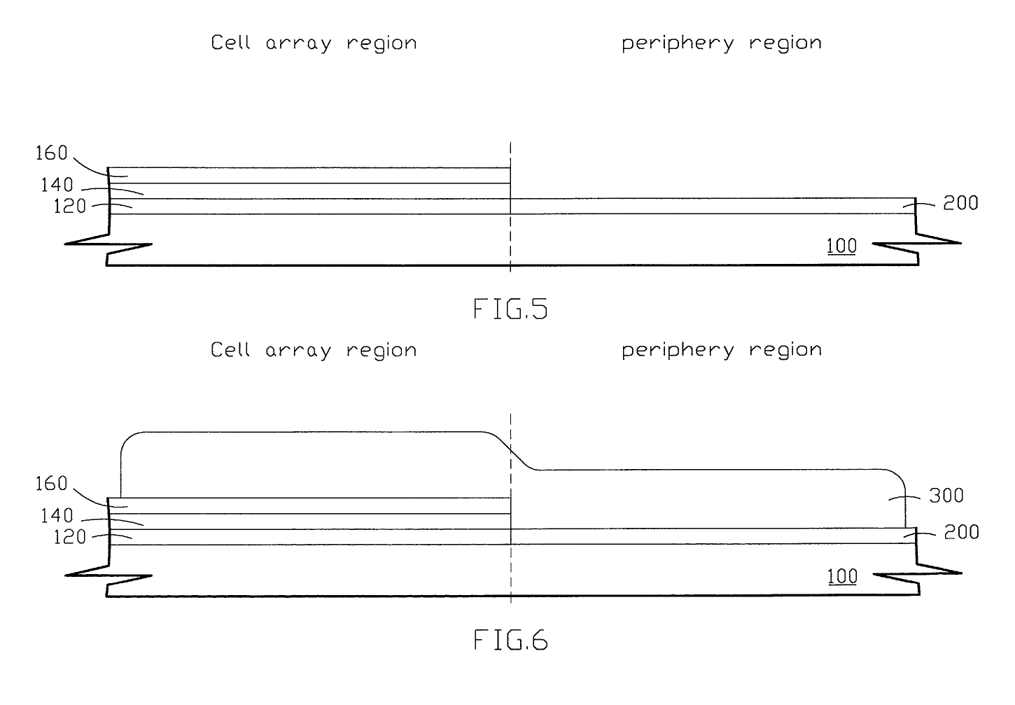

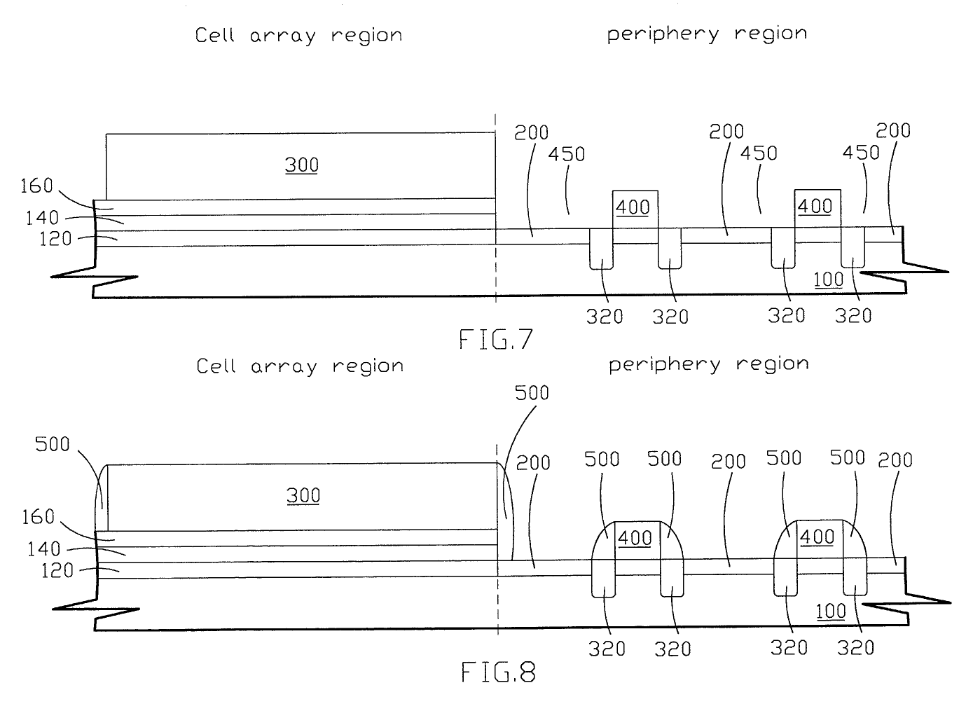

Referring to FIG. 6, a silicon layer 300 is formed on the second oxide layer 160 and the third oxide layer 200. The silicon layer 300 is a gate layer. Referring to FIG. 7, after deciding the location of the gate which is in the periphery region, the partial silicon layer which is in the periphery region is removed by using a photolithography and a etching process to form the plural first gates 400 and the plural first diffusion regions 450 in the periphery region. The plural first diffusion regions 450 are located on the both sides of the plural first gates 400. Then the lightly doped drain region 320 is formed in the plural first diffusion regions 450 by using the lightly doped drain process to decrease the hot carrier effects.

Referring to FIG. 8, after proceeding the lightly doped drain process, the spacer layer is formed on the second oxide layer 160, the silicon layer 300 which is in the cell array region, the plural first gates 400, and the plural first diffusion regions 450. Then the spacer 500 is formed on the sidewalls of the silicon layer 300 which is in the cell array region and the plural first gates 400.

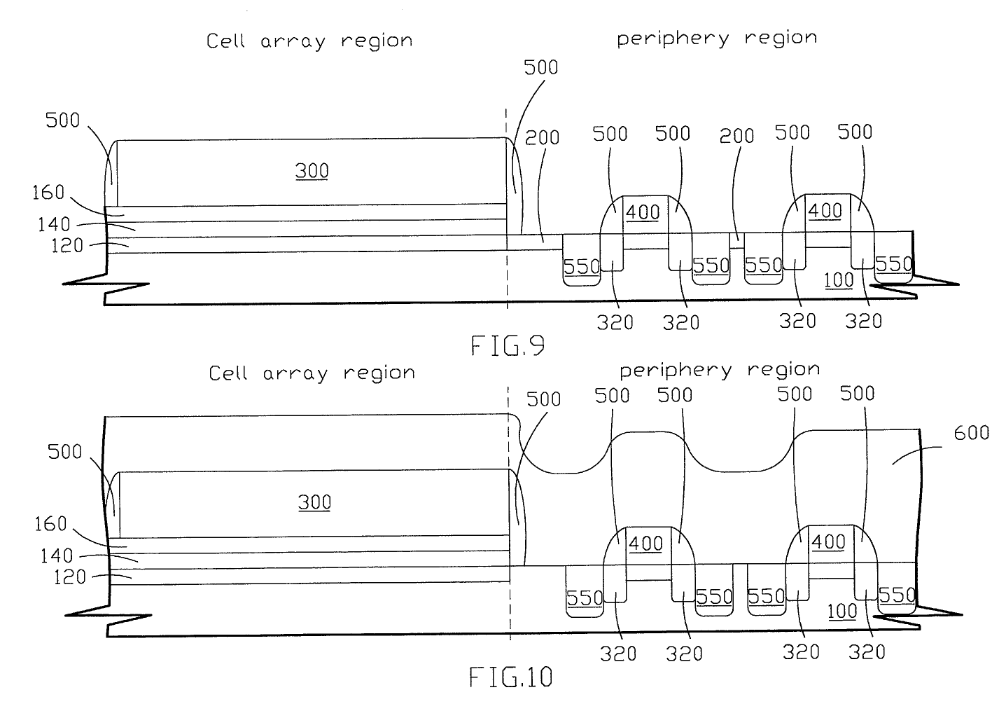

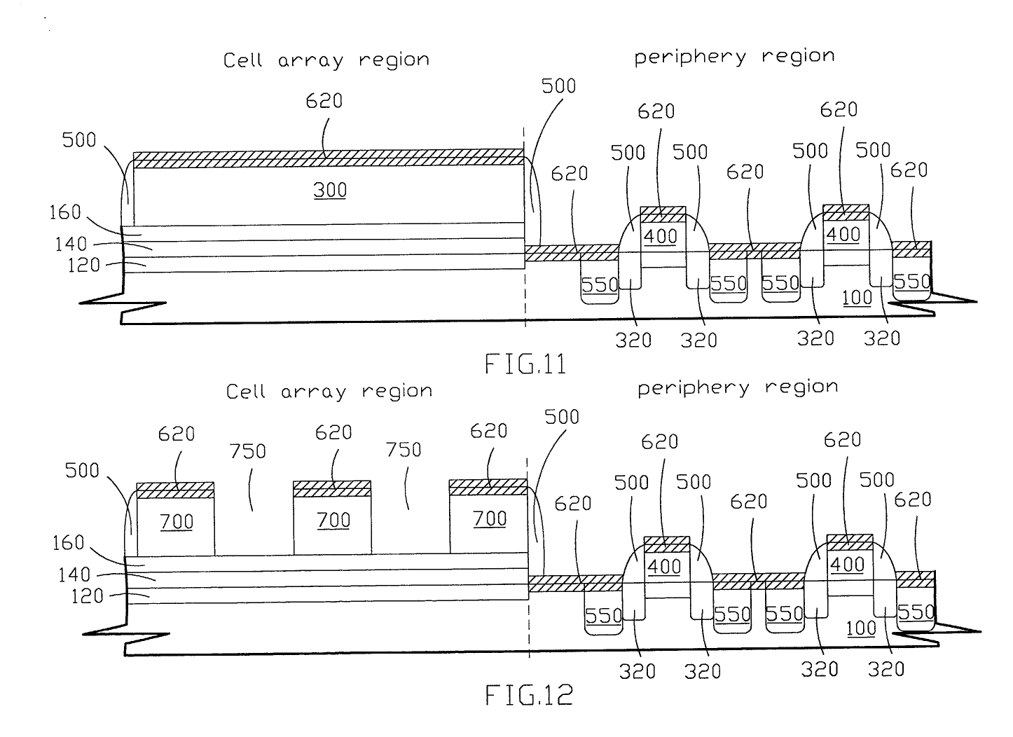

Referring to FIG. 9, after deciding the location of the source/drain region which is in the periphery region, the ions, which are needed in the process, are implanted into the plural first diffusion regions 450 to form the source/drain 550. Referring to FIG. 10, a metal layer 600 is formed on the silicon layer 300 which is in the cell array region, the plural first gates 400, and the plural first diffusion regions 450. Before the metal layer 800 deposition process, the wet etching method is used to clean the oxide which is on the silicon layer and the plural first diffusion regions to form the metal silicide layer easier. The chemical vapor deposition method or the direct current magnetron sputtering method is most used to form the metal layer 600. Then the wafer is placed into the chamber to proceed the first rapid thermal process (RTP). The metal layer 600 will react with the silicon, which is at the contact region, to form the silicide layer. The using temperature of the silicide process is about 500 to 700° C. The structure of the metal silicide which is formed in the first rapid thermal process is a metastable C-49 phase structure with higher resistivity. Referring to FIG. 11, the unreacted and the remained metal layer 600 is removed by applying the RCA cleaning method. Therefore, the silicide layers 620 are existed on the top of the silicon layer 300 which is in the cell array region, the plural first gates 400, and the plural first diffusion regions 450. Finally, the second rapid thermal process is performed to transform higher resistivity of the C-49 phase silicide structure into lower resistivity of the C-54 phase silicide structure. The using temperature of the second rapid thermal process is about 750 to 850° C. The material of the metal layer 600 can be titanium, cobalt, and platinum. Titanium is usually used to be the material of the metal layer 600. In order to co-operate the needs of the procedure, the third oxide layer 200, which is in the plural first diffusion region, is usually removed to increase the qualities of the semiconductor elements.

Titanium is the most common used metallic material for the current salicide process. Basically, titanium is a fine oxygen gettering material, where under an appropriate temperature titanium and silicon at MOS device source/drain and gate regions are easily mutually diffused to form a titanium silicide with very low resistance.

In the salicide process, the silicon layer which is in the cell array region is used to be a mask layer. This mask layer can avoid the silicide layer formed on the second oxide layer 160. Referring to FIG. 12, after finishing the salicide process, the location of the gate which is in the cell array region is decided. Then the partial silicon layer 300 which is in the cell array region is removed by using a photolithography and a etching process to form the plural second gates 700 and the plural second diffusion regions 750 on the second oxide layer 160. The plural second diffusion regions 750 are located on the both sides of the plural second gates 700. In the etching process to remove the partial silicon layer 300 which is in the cell array region, the etching process will stop until etching to the second oxide layer 160, nitride layer 140, or the first oxide layer.

Referring to FIG. 13, after deciding the location of the source/drain region which is in the cell array region, the ions, which are needed in the process, are implanted into the plural second diffusion regions 750 to form the source/drain 770. The boron (B) or the boron fluoride (BF₂) is usually used to be the implanted ions. After forming the source/drain 770 in the cell array region, the ssalicide process is finished.

In accordance with the present invention, the present invention provides a method to decrease the resistance of the word line, which is in the cell array region and periphery region and to avoid the leakage defects occurring in the diffusion region, which is in the cell array region, by using a silicon layer to be the mask layer to form the silicide on the gates, which are in the cell array region and the periphery region, and in the diffusion region, which is in the periphery region successfully. The present invention method can also decrease the resistance of the periphery region. The present invention method can further increase the quality of the semiconductor device and increase the proceeding efficiency of the semiconductor device process.

Although specific embodiments have been illustrated and described, it will be obvious to those skilled in the art that various modifications may be made without departing from what is intended to be limited solely by the appended claims.

What is claimed is:

1. A method for forming a partial salicide, said method comprises:
providing a wafer, said wafer comprises a substrate;
forming a first oxide layer on said substrate;
forming a nitride layer on said first oxide layer;
forming a second oxide layer on said nitride layer;
removing said partial first oxide layer, said partial nitride layer, and said partial second oxide layer to show said substrate in a first region of said wafer;
forming a third oxide layer on said substrate, wherein said substrate is in said first region;
forming a silicon layer on said second oxide layer and said third oxide layer;
removing said partial silicon layer to form a plural first gates and a plural first diffusion regions in said first region, wherein said plural first diffusion regions are located on a side of said plural first gates;
forming a spacer on a sidewall of said plural first gates and said silicon layer;
implanting a ion to form a source/drain region in said plural first diffusion regions;
forming a metal layer on said plural first gates, said plural first diffusion regions, and said silicon layer;
proceeding a rapid thermal process to form a silicide layer on said plural first gates, said plural first diffusion regions, and said silicon layer;
removing said metal layer; and
removing said partial silicon layer and said silicide layer to form a plural second gates and a plural second diffusion regions in a second region of said wafer, wherein said plural second diffusion regions are located on a side of said plural second gates.

2. The method according to claim 1, wherein said a material of said metal layer is titanium.

3. The method according to claim 1, wherein said a material of said metal layer is cobalt.

4. The method according to claim 1, wherein said a material of said metal layer is platinum.

5. The method according to claim 1, wherein said first region is cell array region.

6. The method according to claim 1, wherein said second region is periphery region.

7. A method for forming a partial salicide, said method comprises:
providing a wafer, said wafer comprises a substrate;
forming a first oxide layer on said substrate;
forming a nitride layer on said first oxide layer;
forming a second oxide layer on said nitride layer;
removing said partial first oxide layer, said partial nitride layer, and said partial second oxide layer to show said substrate in a first region of said wafer;
forming a third oxide layer on said substrate, wherein said substrate is in said first region;
forming a silicon layer on said second oxide layer and said third oxide layer;
removing said partial silicon layer to form a plural first gates and a plural first diffusion regions in said first region, wherein said plural first diffusion regions are located on a side of said plural first gates;
forming a lightly doped drain in said plural first diffusion regions;
forming a spacer on a sidewall of said plural first gates and said silicon layer;
implanting a ion to form a source/drain region in said plural first diffusion regions;
forming a metal layer on said plural first gates, said plural first diffusion regions, and said silicon layer;
proceeding a first rapid thermal process to form a silicide layer on said plural first gates, said plural first diffusion regions, and said silicon layer;
removing said metal layer and proceeding a second rapid thermal process; and
removing said partial silicon layer and said silicide layer to form a plural second gates and a plural second diffusion regions in a second region of said wafer, wherein said plural second diffusion regions are located on a side of said plural second gates.

8. The method according to claim 7, wherein said a material of said metal layer is titanium.

9. The method according to claim 7, wherein said a material of said metal layer is cobalt.

10. The method according to claim 7, wherein said a material of said metal layer is platinum.

11. The method according to claim 7, wherein said first region is cell array region.

12. The method according to claim 7, wherein said second region is periphery region.

13. A method for forming a partial salicide, said method comprises:
providing a wafer, said wafer comprises a substrate and said substrate comprises a first region and a second region;
forming a oxide layer on said substrate;
forming a silicon layer on said oxide layer;
removing said partial silicon layer to form a plural first gates and a plural first diffusion regions in said first region, wherein said plural first diffusion regions are located on a side of said plural first gates;
forming a spacer on a sidewall of said plural first gates and said silicon layer;
implanting a ion to form a source/drain region in said plural first diffusion regions;
forming a metal layer on said plural first gates, said plural first diffusion regions, and said silicon layer;
proceeding a rapid thermal process to form a silicide layer on said plural first gates, said plural first diffusion regions, and said silicon layer;
removing said metal layer; and
removing said partial silicon layer and said silicide layer to form a plural second gates and a plural second diffusion regions in a second region of said wafer, wherein said plural second diffusion regions are located on a side of said plural second gates.

14. The method according to claim 13, wherein said a material of said metal layer is titanium.

15. The method according to claim 13, wherein said a material of said metal layer is cobalt.

16. The method according to claim 13, wherein said a material of said metal layer is platinum.

17. The method according to claim 13, wherein said first region is cell array region.

18. The method according to claim 13, wherein said second region is periphery region.
